(19) United States
(12) Patent Application Publication
(10) Pub. No.: US 2014/0177140 A1
(43) Pub. Date: Jun. 26, 2014

(54) ELECTRONIC DEVICE ASSEMBLY

(71) Applicant: Cal-Comp Electronics & Communications Company Limited, (US)

(72) Inventor: Chih-Cheng Wang, New Taipei City (TW)

(73) Assignee: Cal-Comp Electronics & Communications Company Limited, New Taipei City (TW)

(21) Appl. No.: 13/781,731

(22) Filed: Feb. 28, 2013

(30) Foreign Application Priority Data
Dec. 26, 2012 (TW) 101225181

(51) Int. Cl. H05K 5/03

(52) U.S. Cl. CPC H05K 5/03
USPC 361/679.01

(57) ABSTRACT

An electronic device assembly including an electronic device, a protection cover, a transmission wire and a pair of connecting ports is provided. The protection cover with the transmission wire embedded therein is detachably disposed around the electronic device. The connecting ports are disposed at two ends of the transmission wire respectively. The protection cover provides protection effects when the protection cover is assembled with the electronic device and provides enough length to make two electronic devices electronically connected conveniently when the protection cover is disassembled from the electronic device.

### CROSS-REFERENCE TO RELATED APPLICATION

This application claims the priority benefit of Taiwan application serial no. 101225181, filed on Dec. 26, 2012. The entirety of the above-mentioned patent application is hereby incorporated by reference herein and made a part of this specification.

### BACKGROUND OF THE INVENTION

1. Field of the Invention

The present invention generally relates to an electronic device assembly, in particular, to an electronic device assembly of a protection cover and an electronic device.

2. Description of Related Art

When being carried or used, a portable electronic device may be scratched causing defects on its casing, or be impacted causing damage and failure of electronic elements therein. To solve this problem, a protection cover is usually used.

FIG. 1 is a schematic view of a conventional protection cover, and FIG. 2 is a schematic view of the conventional protection cover assembled with an electronic device. Referring to FIG. 1 and FIG. 2, the protection cover 100 of FIG. 1 is an elastic mesh-type protection cover 100, and the electronic device 150 is an external hard disk. As shown in FIG. 2, the protection cover 100 of FIG. 1 is sleeved over the electronic device 150. Although a transmission connector 110 connected to the mesh-type protection cover 100 is additionally provided, it can be seen from FIG. 1 and FIG. 2 that limited by the design of the mesh part of the mesh-type protection cover 100, no wire is disposed in the mesh part; thus the mesh part can only be fixed to the hard disk to provide protection effects. Also, to satisfy the user's habit of storing the electronic device 150, the transmission connector 110 protruding out of the electronic device 150 is designed in accordance with the size of the electronic device 150. As a result, when the electronic device 150 is connected to another electronic device 150 by using the transmission connector 110, they cannot be used conveniently because the transmission connector 110 is too short.

### SUMMARY OF THE INVENTION

Accordingly, the present invention is directed to an electronic device assembly that is convenient to use.

The present invention provides an electronic device assembly, including an electronic device, a protection cover, a transmission wire and a pair of connecting ports. The protection cover with the transmission wire embedded therein is detachably disposed around the electronic device. The connecting ports are disposed at two ends of the transmission wire respectively.

Based on the above, in the electronic device assembly of the present invention, the transmission wire is embedded in the protection cover, and the protection cover is disposed around the electronic device, so as to protect the electronic device without requiring a large volume. When it is intended to electrically connect the electronic device to another electronic device, the protection cover is detached from the electronic device, and the protection cover with the transmission wire embedded therein provides enough length to make the two electronic devices electronically connected through the two connecting ports.

In order to make the aforementioned and other objectives and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a conventional protection cover.

FIG. 2 is a schematic view of the conventional protection cover assembled with an electronic device.

FIG. 3 is a schematic view of an electronic device assembly according to a first embodiment of the present invention.

FIG. 4 is a sectional view taken along Line A-A in FIG. 3.

FIG. 5 is a perspective view of the electronic device and the protection cover in FIG. 3 assembled with each other.

FIG. 6 is a schematic view of the electronic device assembly in FIG. 3 electrically connected to another electronic device.

FIG. 7 is a schematic view of an electronic device assembly according to a second embodiment of the present invention.

FIG. 8 is a schematic view of an electronic device assembly according to a third embodiment of the present invention.

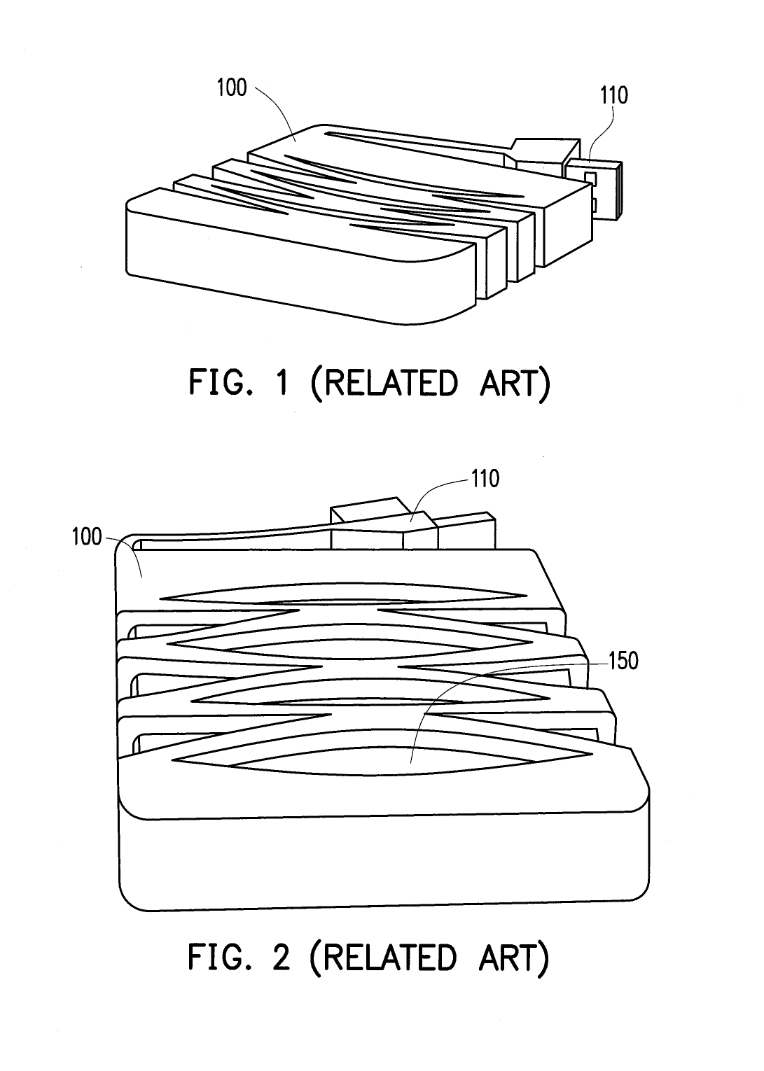

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

### First Embodiment

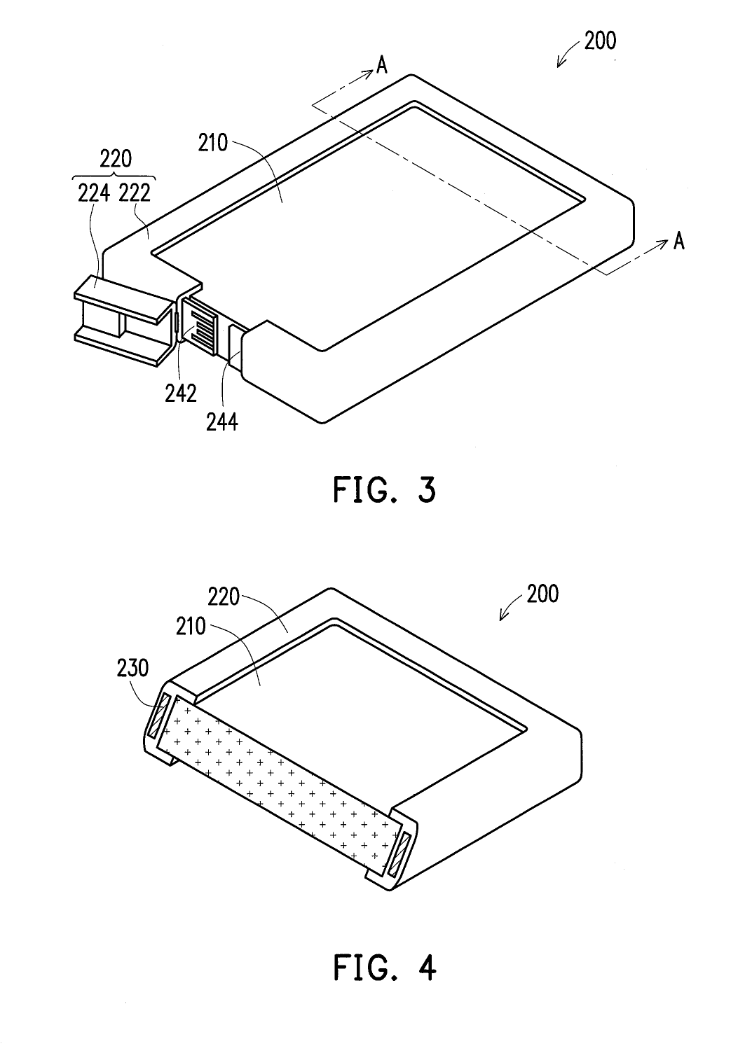

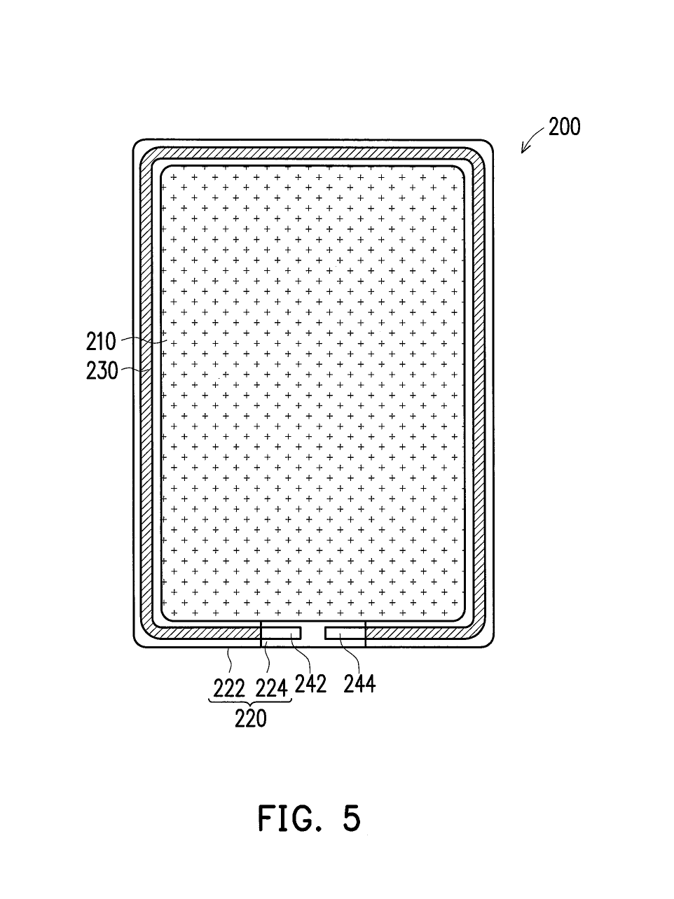

FIG. 3 is a schematic view of an electronic device assembly according to a first embodiment of the present invention, FIG. 4 is a sectional view taken along Line A-A in FIG. 3, and FIG. 5 is a perspective view of the electronic device and the protection cover in FIG. 3 assembled with each other. Referring to FIG. 3, FIG. 4 and FIG. 5, the electronic device assembly 200 includes an electronic device 210, a protection cover 220, a transmission wire 230 and a pair of connecting ports 242 and 244. The protection cover 220 with the transmission wire 230 embedded therein is detachably disposed around the electronic device 210. The connecting ports 242 and 244 are disposed at two ends of the transmission wire 230 respectively.

In this embodiment, the electronic device 210 may be a portable electronic device 210 such as an external hard disk, a mobile phone or a portable tablet computer, but the type of the electronic device 210 is not limited to those listed above. In addition, the protection cover 220 has a main body 222 and a cap portion 224 that are connected to each other. One side of the cap portion 224 that is connected to the main body 222 is adapted to be detached from the main body 222. When the protection cover 220 is disposed around the electronic device 210, the main body 222 surrounds the electronic device 210 and makes the two connecting ports 242 and 244 close to each other at the same side of the electronic device 210. The cap portion 224 is used for covering the connecting ports 242 and 244, so that as shown in FIG. 5, the connecting ports 242 and 244 will not be exposed out of the protection cover 220. Therefore, the electronic device assembly 200 has an integral appearance, and is easily stored by a user.

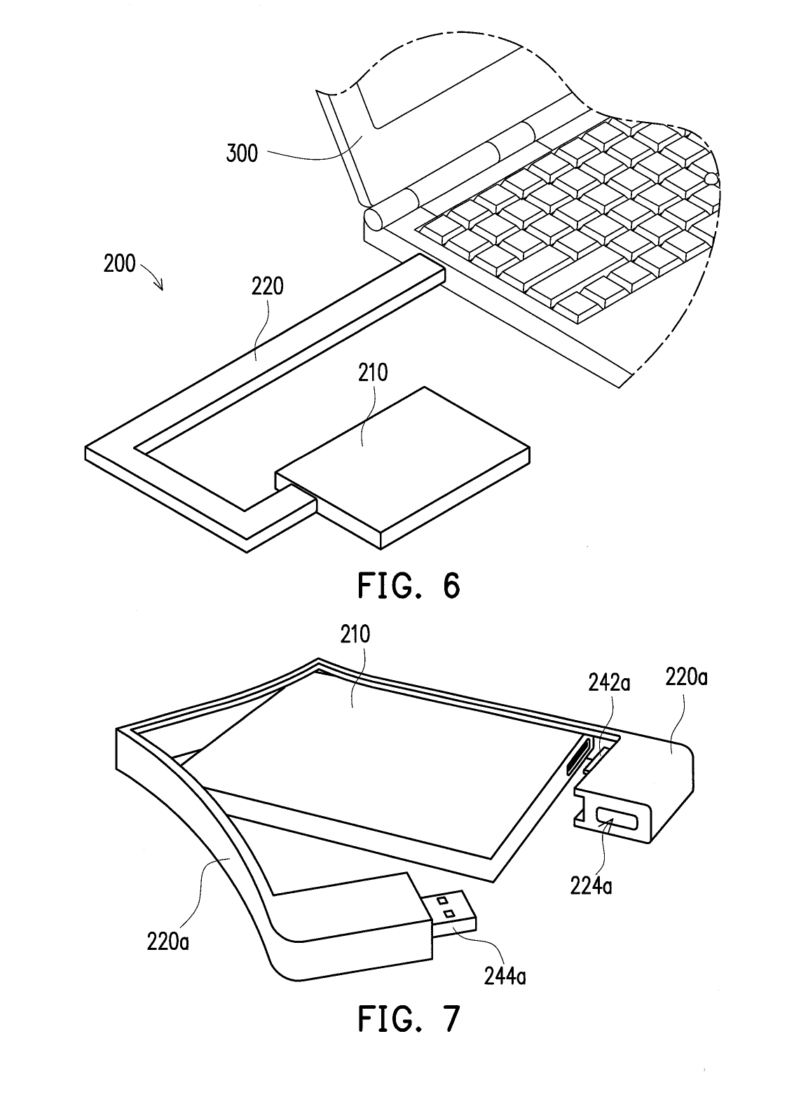

FIG. 6 is a schematic view of the electronic device assembly in FIG. 3 electrically connected to another electronic device 300. Referring to FIG. 6, when it is intended to electrically connect the electronic device assembly 200 to another electronic device 300 (for example, a notebook computer), first, the cap portion 224 is pivoted about the side thereof that is connected to the main body 222 so that the side of the cap portion 224 that is not connected to the main body 222 is detached from the main body 222, so as to release the connecting ports 242 and 244 from the cap portion 224; then, the protection cover 220 surrounding the electronic device 210 is detached from the electronic device 210, the connecting port 242 is plugged into the electronic device 210, and the connecting port 244 is plugged into the other electronic device 300.

It should be particularly noted that since the transmission wire 230 is embedded in the whole protection cover 220 and has approximately the same length as that of the main body of the protection cover 220, and the length of the main body of the protection cover 220 approximates the sum of the lengths of the four sides of the electronic device 210, the transmission wire 230 (the protection cover 220) provides enough length for the user when the electronic device 210 is electrically connected to the other electronic device 300 through the protection cover 220 with the transmission wire 230 embedded therein, thereby providing great convenience in use for the user.

Furthermore, in the above implementation, the cap portion 224 is provided with a structure capable of directly covering the connecting ports 242 and 244 so that the protection cover 220 can be fixed to the electronic device 210; however, the protection cover 220 may also be fixed to the electronic device 210 through other implementations as long as the same objective (of fixing the protection cover 220 to the electronic device 210) can be achieved. For example, in another embodiment not shown, the cap portion 224 may further have an insertion opening at the side thereof that is not connected to the main body 222, so that the connecting ports 242 and 244 having interfaces facing the insertion opening are correspondingly plugged into the insertion opening. Thus, the objective of fixing the protection cover 220 to the electronic device 210 can also be achieved.

### Second Embodiment

This embodiment is approximately the same as the first embodiment, where the same or like reference numbers are used to denote the same or like elements, description of which will be omitted, and only the difference between the two embodiments will be detailed below.

FIG. 7 is a schematic view of an electronic device assembly according to a second embodiment of the present invention. Referring to FIG. 7, the difference between this embodiment and the first embodiment lies in that when the protection cover 220a is disposed around the electronic device 210, the connecting port 242a is correspondingly plugged into the electronic device 210, and the connecting port 244a is correspondingly plugged into an insertion opening 224a of the cap portion 224.

In detail, when the protection cover 220a is disposed around the electronic device 210 to protect the electronic device 210, the plugging direction of the connecting port 242a correspondingly plugged into the electronic device 210 is perpendicular to the plugging direction of the connecting port 244a correspondingly plugged into the cap portion 224.

Through such a configuration, the state that the connecting port 242a is plugged into the electronic device 210 to be protected by the protection cover 220a is maintained, and the connecting port 244a can be taken out and connected to another electronic device 300 as required.

### Third Embodiment

This embodiment is approximately the same as the first embodiment, where the same or like reference numbers are used to denote the same or like elements, description of which will be omitted, and only the difference between the two embodiments will be detailed below.

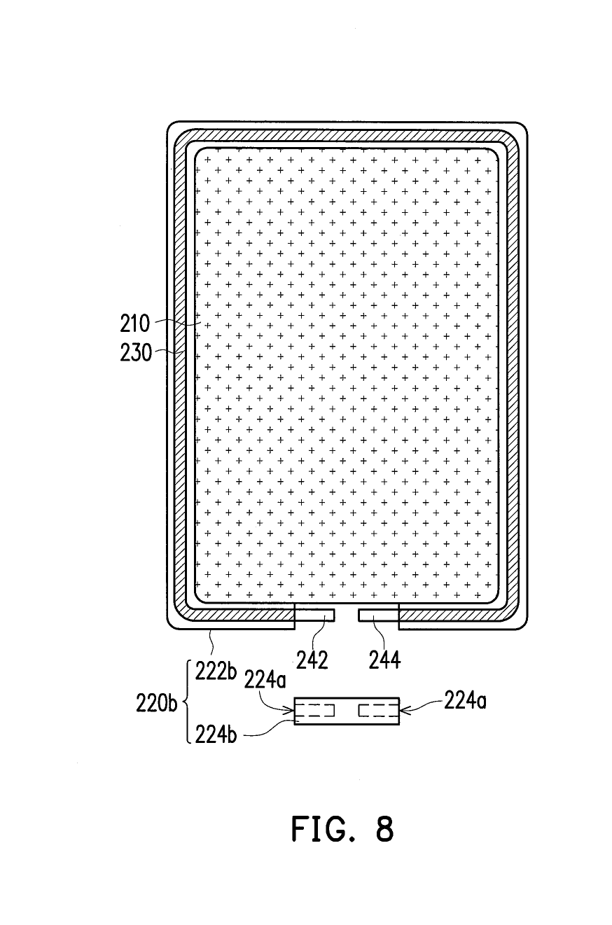

FIG. 8 is a schematic view of an electronic device assembly according to a third embodiment of the present invention. Referring to FIG. 8, the difference between this embodiment and the first embodiment lies in that in this embodiment, the protection cover 220b includes a main body 222b and a cap portion 224b that are detachable from each other, the connecting ports 242 and 244 are disposed at two ends of the main body 222b respectively, and the cap portion 224b has two insertion openings 224a into which the connecting ports 242 and 244 facing each other are correspondingly plugged.

It can be seen from the above that, when it is intended to electrically connect the electronic device 210 to another electronic device 300 (as shown in FIG. 6), the cap portion 224b needs to be detached from the main body 222b first, and then the two connecting ports 242 and 244 are plugged into the different electronic devices 210 and 300 respectively.

Based on the above, in the electronic device assembly of the present invention, since the transmission wire is embedded in the whole protection cover and has approximately the same length as that of the main body of the protection cover, and the length of the main body of the protection cover approximates the sum of the lengths of the four sides of the electronic device, the transmission wire (the protection cover) provides enough length for the user when the electronic device is electrically connected to the other electronic device through the protection cover with the transmission wire embedded therein, thereby providing great convenience in use for the user.

Moreover, the cap portion of the protection cover is used for covering the connecting ports, so that compared with the prior art, in the electronic device assembly of the present invention, the connecting ports will not be exposed out of the protection cover. Therefore, the electronic device assembly has an integral appearance, and is easily stored by a user.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic device assembly, comprising:
an electronic device;
a protection cover, detachably disposed around the electronic device;
a transmission wire, embedded in the protection cover; and
a pair of connecting ports, disposed at two ends of the transmission wire respectively.

2. The electronic device assembly according to claim 1, wherein the electronic device is an external hard disk, a mobile phone or a portable tablet computer.

3. The electronic device assembly according to claim 1, wherein the protection cover comprises a main body and a cap portion.

4. The electronic device assembly according to claim 3, wherein one side of the cap portion is connected to the main body, and the other side of the cap portion that is not connected to the main body is adapted to be detached from the main body.

5. The electronic device assembly according to claim 4, wherein the cap portion covers the connecting ports.

6. The electronic device assembly according to claim 4, wherein the cap portion comprises an insertion opening, and one of the connecting ports is correspondingly plugged into the insertion opening.

7. The electronic device assembly according to claim 6, wherein the other one of the connecting ports is correspondingly plugged into the electronic device.

8. The electronic device assembly according to claim 3, wherein the cap portion and the main body are detachable from each other, the connecting ports are disposed at two ends of the main body respectively, and the cap portion comprises two insertion openings facing and correspondingly being plugged into each other.
